(19) United States
(12) Patent Application Publication
(10) Pub. No.: US 2014/0062605 A1
(43) Pub. Date: Mar. 6, 2014

(54) METHOD AND APPARATUS FOR A SYNTHESIZER ARCHITECTURE

(71) Applicants: Robert E. Stengel, Pompano Beach, FL (US); Stephen B. Einbinder, Plantation, FL (US); Jeffrey B. Wilhite, Barrington, IL (US)

(72) Inventors: Robert E. Stengel, Pompano Beach, FL (US); Stephen B. Einbinder, Plantation, FL (US); Jeffrey B. Wilhite, Barrington, IL (US)

(73) Assignee: MOTOROLA SOLUTIONS, INC., SCHAUMBURG, IL (US)

(21) Appl. No.: 13/601,488

(22) Filed: Aug. 31, 2012

(51) Int. Cl. H03L 7/16

(52) U.S. Cl. CPC H03L 7/16
USPC 331/34

(57) ABSTRACT

A synthesizer architecture, responsive to a low noise reference signal from a discrete oscillator, provides a continuous periodic output with a period that is a fractional multiple of the low noise reference signal. One exemplary embodiment includes a phase detector providing a control signal to a selected one of a plurality of integrated voltage controlled oscillators (VCO), wherein the phase detector is a sub-harmonic continuous time sampling phase detector. Another exemplary embodiment includes a continuous fractional divider input to the phase detector in response to an output of the selected VCO. Yet another exemplary embodiment comprises an injection locked ring oscillator responsive to the low noise narrow band variable reference signal with a fractional output period.

### FIELD OF THE DISCLOSURE

The present disclosure relates generally to a frequency generator and more particularly to a wideband frequency generator providing a continuous periodic output.

### BACKGROUND

In modern radio applications there is an energetic pursuit of greater bandwidths to gain greater utility and coverage. Transceiver specifications demand a very low noise solution and an even tougher non-harmonic spur requirement. One known method for accomplishing greater bandwidths includes selecting one of a plurality of multiple discrete voltage controlled oscillators (VCOs) when required, thus covering the entire frequency range of interest. However, many discrete VCOs may be needed to cover the desired frequency range, which would be extremely expensive in terms of space, reliability, and cost.

Digital methods involving manipulating very fast timing to attain clean noise specification typically mean very high currents. The low spur requirements necessitate that the timing must be controlled very precisely to produce spurious free performance. And analog frequency generation involves oscillators with resonators that have a very high Q factor. Q factor is a dimensionless parameter that describes how under-damped an oscillator or resonator is, or equivalently, characterizes a resonator's bandwidth relative to its center frequency. Higher Q indicates a lower rate of energy loss relative to the stored energy of the oscillator.

Accordingly, there is a need for a method and synthesizer architecture that provides a continuous periodic broadband response with very low noise and spurious emission and that is capable of meeting high specification portable and mobile radio requirements.

### BRIEF DESCRIPTION OF THE FIGURES

The accompanying figures, where like reference numerals refer to identical or functionally similar elements throughout the separate views, together with the detailed description below, are incorporated in and form part of the specification, and serve to further illustrate embodiments of concepts that include the claimed invention, and explain various principles and advantages of those embodiments.

FIG. 1 is a block diagram of a synthesizer architecture in accordance with an exemplary embodiment;

FIG. 2 is a flow chart of a method in accordance with the exemplary embodiment of FIG. 1;

FIG. 3 is a block diagram of a synthesizer architecture in accordance with yet another exemplary embodiment;

FIG. 4 is a graph of a frequency plan in accordance with the exemplary embodiment of FIG. 3;

FIG. 5 is a table of simulated values in accordance with the exemplary embodiment of FIG. 3 in a receive mode;

FIG. 6 is a table of simulated values in accordance with the exemplary embodiment of FIG. 3 in a transmit mode;

FIG. 7 is a flow chart of a method in accordance with the exemplary embodiment of FIG. 3;

FIG. 8 is a block diagram of a synthesizer architecture in accordance with still another exemplary embodiment; and

FIG. 9 is a block diagram of a synthesizer architecture in accordance with yet another exemplary embodiment.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

The apparatus and method components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

### DETAILED DESCRIPTION

A synthesizer architecture is configured to be coupled to a discrete voltage controlled oscillator, the synthesizer architecture includes an integrated portion coupled to the discrete voltage controlled oscillator to form a first phase locked loop wherein the discrete voltage controlled oscillator is configured to provide a low noise reference signal; and circuitry coupled to the discrete voltage controlled oscillator and configured to provide, in response to the low noise reference signal, a continuous periodic output with a period that is a fractional multiple of the low noise reference signal period.

One exemplary embodiment includes an arrangement of a phase detector responsive to the low noise narrow band variable reference signal and providing a control signal to a selected one of a plurality of integrated VCOs, wherein the phase detector is a fractional sub-harmonic continuous time phase detector. Another exemplary embodiment includes a continuous fractional divider programmed to the variable reference signal at the phase detector in response to an output of the selected integrated VCO. Yet another exemplary embodiment comprises an injection locked ring oscillator responsive to the low noise narrow band variable reference signal with a fractional offset.

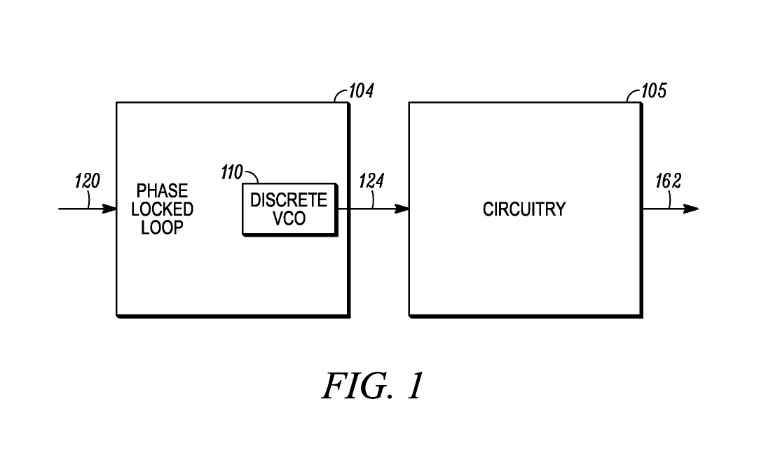

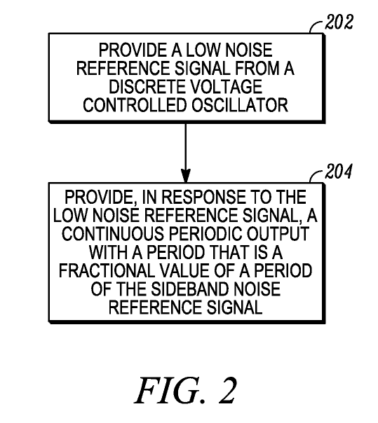

Referring to FIGS. 1 and 2, a phase locked loop (PLL) 104 is responsive to a reference signal 120 and includes a discrete VCO 110 that provides 202 a PLL output 124 (a low noise reference signal). Circuitry 105 provides 204 a carrier frequency signal 162 that is a continuous periodic output with a period that is a predetermined fractional multiple of a period of the reference signal 124, in response to the PLL output 124.

In one exemplary embodiment, the synthesizer architecture includes two cascaded phase locked loops (PLLs), one with a narrow bandwidth and one with a wide bandwidth. A PLL is a closed-loop frequency-control system based on the phase difference between an input clock signal and a feedback clock signal of a controlled oscillator. The narrow bandwidth PLL typically is a conventional fractional N synthesizer including a discrete VCO. This narrow bandwidth PLL generates a low noise narrow band variable reference signal for the wide bandwidth PLL. The wide bandwidth PLL is a fully integrated circuit providing a continuous periodic output having a broad range of frequencies that can be generated with low noise and minimal spurious emissions.

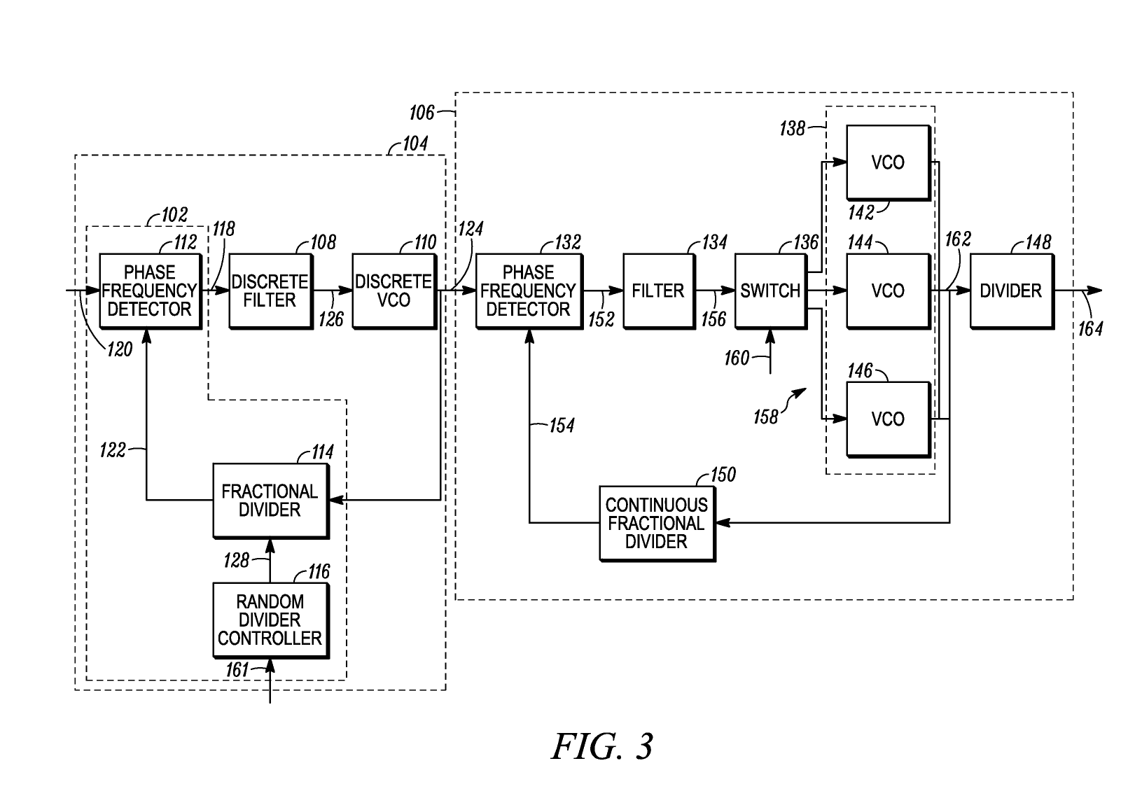

More specifically, referring to FIG. 3, this exemplary embodiment includes the synthesizer architecture having an integrated circuit including a first PLL 104 and a second PLL 106. The first PLL 104 includes an integrated portion 102, a discrete low pass filter 108 and a discrete VCO 110. The first PLL 104 produces an output 124 having a narrow frequency range, while the second PLL 106 is configured to provide a carrier frequency signal 164 selectable from a wide frequency range of signals.

The first PLL 104 includes, in addition to the discrete low pass filter 108 and discrete VCO 110, a phase frequency detector 112, a fractional divider 114, and a random divider controller 116. The phase frequency detector 112 provides an “up” or “down” control signal 118 to the discrete low pass filter 108 in response to a reference signal 120 and a feedback signal 122 from the fractional-N divider 114. The discrete VCO 110 provides a first PLL output 124 to the second PLL 106 and the fractional-N divider 114 in response to a steering signal 126 from the discrete low pass filter 108. The fractional-N divider 114 further receives a fractional-N programming signal 128 from the random divider controller 116 responsive to a programming signal 161 and the output 124 frequency.

The phase frequency detector 112 detects the difference in phase and frequency between the reference signal 120 and feedback signal 122 and generates the “up” or “down” control signal 118 based on whether the feedback signal 122 is lagging or leading the reference signal 120. These “up” or “down” control signals determine whether the VCO 110 needs to operate at a higher or lower frequency, respectively. The phase frequency detector 112 provides these “up” and “down” control signals 118 to a charge pump (not shown). If the charge pump receives an up signal, current is driven into the discrete low pass filter 108. Conversely, if it receives a down signal, current is drawn from the discrete low pass filter 108. When the reference signal 120 and the feedback signal 122 are aligned, the first PLL 104 is “locked”.

The second PLL 106 includes a phase detector 132, a low pass filter 134, VCO selection circuitry 136, a bank 138 of integrated VCOs 142, 144, 146 coupled to the VCO selection circuitry via conductors 158, an output divider 148, and a continuous fractional divider 150. The phase detector 132 provides a control signal 152 to the low pass filter 134 in response to the first PLL output 124 and a continuous fractional divider output 154. The low pass filter 134 provides a steering signal 156 to the VCO selection circuitry 136 in response to the control signal 152. The selection circuitry 136 selects one of the integrated VCOs 142, 144, 146, as partially determined by the select signal 160, for receiving the steering signal 156 via the selected one of the conductors 158. The integrated voltage controlled oscillator output 162 from the selected integrated VCO 142, 144, 146 is provided to the continuous fractional divider 150 and to the output divider 148, which provides the desired carrier frequency signal 164.

The integrated portion 102 (narrow bandwidth PLL) and second PLL 106 (wide bandwidth PLL) may be completely integrated. The bank of integrated VCOs 138 are configured to cover a wide range at high frequencies (2.2-3.8 GHz) and can be integrated easily using a differential topology and a spiral coil. The integrated voltage controlled oscillator output 162 from the selected integrated VCO 142, 144, 146 is divided by the output divider 148 down to the desired carrier frequency signal 164. The wide bandwidth PLL 106 defined by the low pass filter 134 is wide enough to track out a large portion of the phase noise inherent in the integrated VCOs 142, 144, 146. A typical phase noise requirement of hand held communication radios of −150 dBc/Hz at a 1 MHz offset requires that the loop bandwidth be wide enough to clean up the 1 MHz noise in the integrated VCOs 142, 144, 146.

One objective, for mobile radios for example, of the described exemplary embodiment addresses covering all frequencies from 100 MHz up to 941 MHz. This coverage is accomplished by varying the first PLL 104 (narrow loop bandwidth synthesizer defined by the discrete low pass filter 108) over a small carrier frequency range and using it as a high quality, low phase noise reference clock for the second PLL 106 (wide loop bandwidth synthesizer defined by low pass filter 134). With the right scheme of fractional-N dividers 114, 150 and integrated VCOs 142, 144, 146, the entire 100 to 941 MHz carrier frequency range can be realized. The second PLL 106 multiplies the frequency range supplied by the first PLL 104 by either 3.5, 3, or 2.5 by using a selectable continuous fractional divider 150. The divide by 2.5 or 3.5 are implemented as a continuous fractional divider 150. The continuous time fractional divider output 154, has a continuous periodic output with a period that is a fractional multiple of the integrated voltage controlled oscillator output 162 period. This continuous fractional divider 150 output signal 154 results is a significant reduction in the number and level of non-harmonic spurious signals generated from a non-continuous time fractional divider, such as fractional-N divider 114 of the first PLL 104 that generates spurious signals within the frequency bandwidth of the low pass filter 134. The limited sub harmonic spurs generated by the continuous time divider 150 are all at a much higher frequency than the second 106 PLL loop bandwidth defined by low pass filter 134. A plurality of output dividers 148 may be cascaded to arrive at the final carrier frequency.

An example of a plan for obtaining desired frequencies follows. Considering a transmit (Tx) frequency plan, the output frequency can be defined by the following relationship:

Fₒᵤₜ=F_{ref}*Nₒ/(Nₖ*Nᵣ)

### Where:

Fref=The variable reference frequency sourced 124 from the narrow synthesizer, range (1005-1255 MHz)
Nₒ Loop Divider 150 value, Range: (3.5, 3, 2.5)
Nₖ Output Divider 148 value, Range: (2, 3, 4, 6, 8)
Nᵣ Divider (not shown) value, Range: (1, 2, 4, 8)

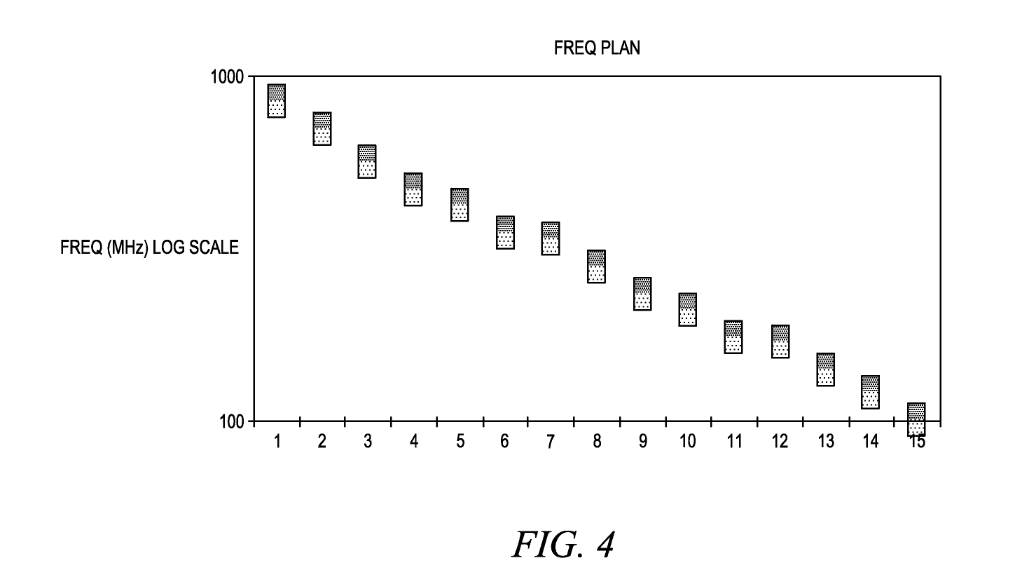

FIG. 4 shows 16 bands providing complete coverage from 98 MHz up to 941 MHz, where
Ref Osc L is 110 with output 124
No is divider 150, with values 2.5, 3, or 3.5, and output 154
Nk is divider 148 with values 2, 3, 4, 6, or 8 and output 164
Fvco is integrated VCO output signal 162 frequency range 2.2 to 3.8 GHz
Frod is F_{VCO}/Nk
Frx is F_{rod}/Nr (Nr is not shown)
Ref Osc H is 110 with output 124

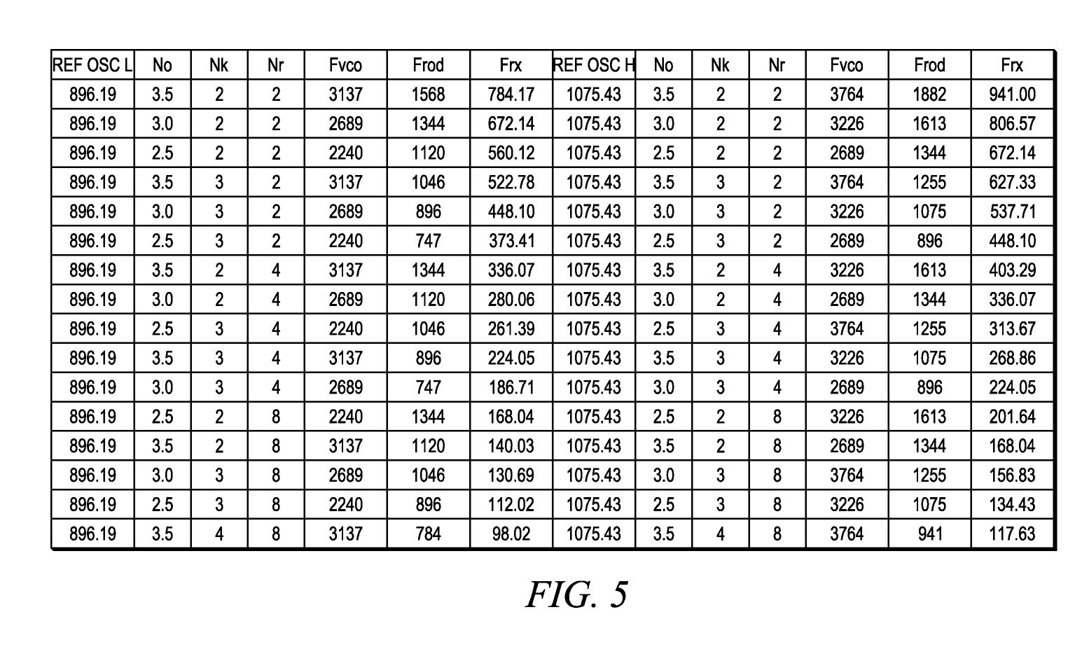

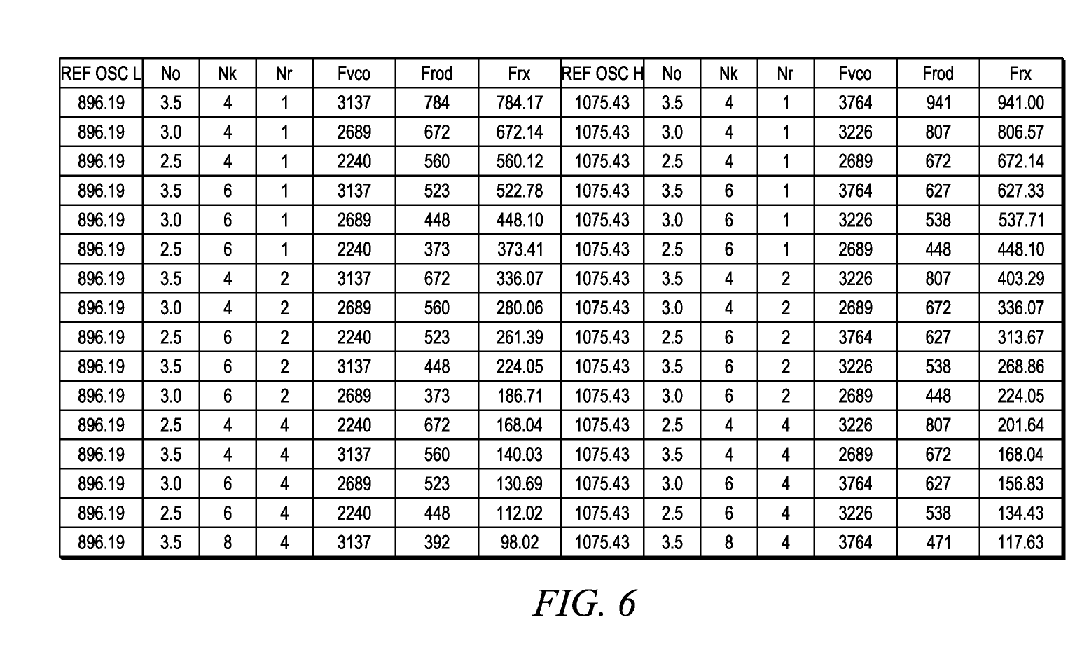

Referring now to FIGS. 5 and 6, tables of simulated values are provided in association with the synthesizer architecture depicted in FIG. 3 operating in a receive mode (FIG. 5) and a transmit mode (FIG. 6). Each row in the table of FIG. 5 represents the complete range of the narrow bandwidth fractional synthesizer applied to the wide bandwidth synthesizer with a given set of dividers. Notice that the full range of the bank of integrated VCOs 138 is 2240-3764 MHz. FIG. 4 shows the plot of frequencies attained with each divider value set. Continuous frequency coverage is desired so that all bands can be reached by the second PLL 106 output frequency range. Inspection of FIG. 5 (receive mode) and FIG. 6 (transmit mode) reveals this to be true.

The first PLL 104 (narrow bandwidth) effectively provides a continuously tunable carrier frequency to be used as a high quality, low phase noise output 124 for the second PLL 106 (wide bandwidth). Phase noise at offset frequencies below the loop bandwidth of 10 MHz is essentially considered to be in-band noise for the second PLL 106. Thus, the noise of the first PLL 104 must be sufficiently low to yield satisfactory performance. Two frequencies of particular interest, for example, are 25 KHz and 1 MHz offset frequencies. The 25 KHz offset frequency is most relevant in receiver discussions since it impacts the two tone intermodulation ratio (IMR) and adjacent channel rejection. This 25 KHz offset noise found in a transmitted signal is also a potential interference signal to receivers in close proximity (location) to the transmitter. The 1.0 MHz offset is a requirement that is particularly important in both the transmit and receive modes. Thus, the first PLL 104 will limit the in band performance of the second PLL 106. Analysis of one exemplary receiver shows that a noise level of −126 dBc/Hz @ 25 KHz offset is required for proper IMR performance (80 dB IMR) at all channels. This dictates the specification for the discrete VCO 110. At 1.0 MHz offset, the phase noise must be far less than −150 dBc/Hz for minimal impact on the composite closed loop system performance. These two performance parameters are strictly determined by the discrete VCO 110 phase noise. Therefore, the discrete VCO 110 is designed to meet the following requirements for this example:

Phase Noise: −124.85 dBc/Hz @ 25 KHz offset (MAX)
−156.85 dBc/Hz @>1 MHz offset (MAX)

By splitting the 180 MHz coverage into two bands, this ensures the high performance requirement.

When a new carrier frequency 162 is programmed 161 (voltage controlled oscillator output 124 into random divider controller 116), the first PLL 104 must be locked first. Programming value 161 adjusts discrete VCO output frequency 124 coupled into fractional divider 114 to an output signal 122 frequency coupled into phase detector 112 equal to the reference frequency signal 120. The sequence of events is the same that occurs with known fractional synthesizers. There is usually some sort of “adapt” period in which the discrete low pass filter 108 is widened for a short duration to get the discrete low pass filter 108 charged and then the loop is narrowed to clean up the noise and fractional-N divider 114 spurs. The adapt time period is generally in the multi-millisecond range. Once locked, this first PLL output 124 is applied to the reference port of the second PLL 106 and can be used to provide the reference frequency for the wide bandwidth PLL. Once the first PLL 104 reference frequency output 124 is settled, one of the integrated VCOs 142, 144, 146 can be activated. This exemplary embodiment includes three integrated VCOs 142, 144, 146, each containing two bands.

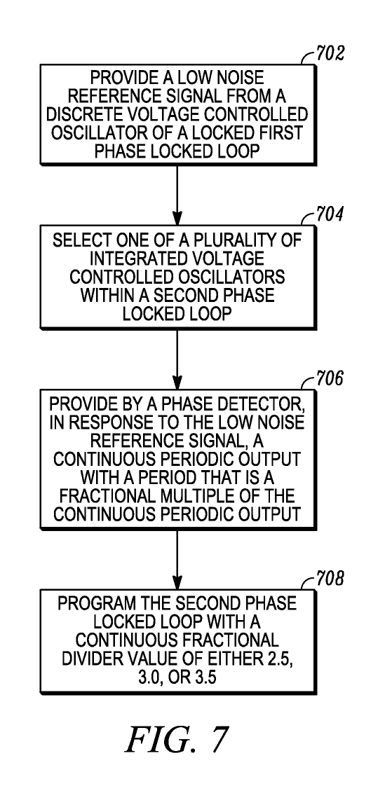

FIG. 7 is a flow chart that illustrates an exemplary embodiment of a synthesizer architecture process 700 in accordance with an exemplary embodiment. Process 700 represents one implementation of a method for an exceptional broadband response with very low noise and spurious emission and that is capable of meeting high specification portable and mobile radio requirements. The various tasks performed in connection with process 700 may be performed by software, hardware, firmware, or any combination thereof. For illustrative purposes, the following description of process 700 may refer to elements mentioned above in connection with FIG. 7. In practice, portions of process 700 may be performed by different elements of the described system, e.g., a processor, a display element, or a data communication component. It should be appreciated that process 700 may include any number of additional or alternative tasks, the tasks shown in FIG. 7 need not be performed in the illustrated order, and process 700 may be incorporated into a more comprehensive procedure or process having additional functionality not described in detail herein. Moreover, one or more of the tasks shown in FIG. 7 could be omitted from an embodiment of the process 700 as long as the intended overall functionality remains intact.

Referring to FIG. 7, the method of operating the synthesizer architecture of FIG. 3 includes providing 702 a low noise reference signal from a discrete voltage controlled oscillator of a locked first phase locked loop 104, selecting 704 one of a plurality of integrated voltage controlled oscillators 138 within a second phase locked loop, providing 706 by a phase detector 132, in response to the low noise reference signal, a continuous periodic output with a period that is a fractional multiple of the continuous periodic output, and programming 708 the second phase locked loop 106 with a continuous fractional divider value of either 2.5, 3.0, or 3.5.

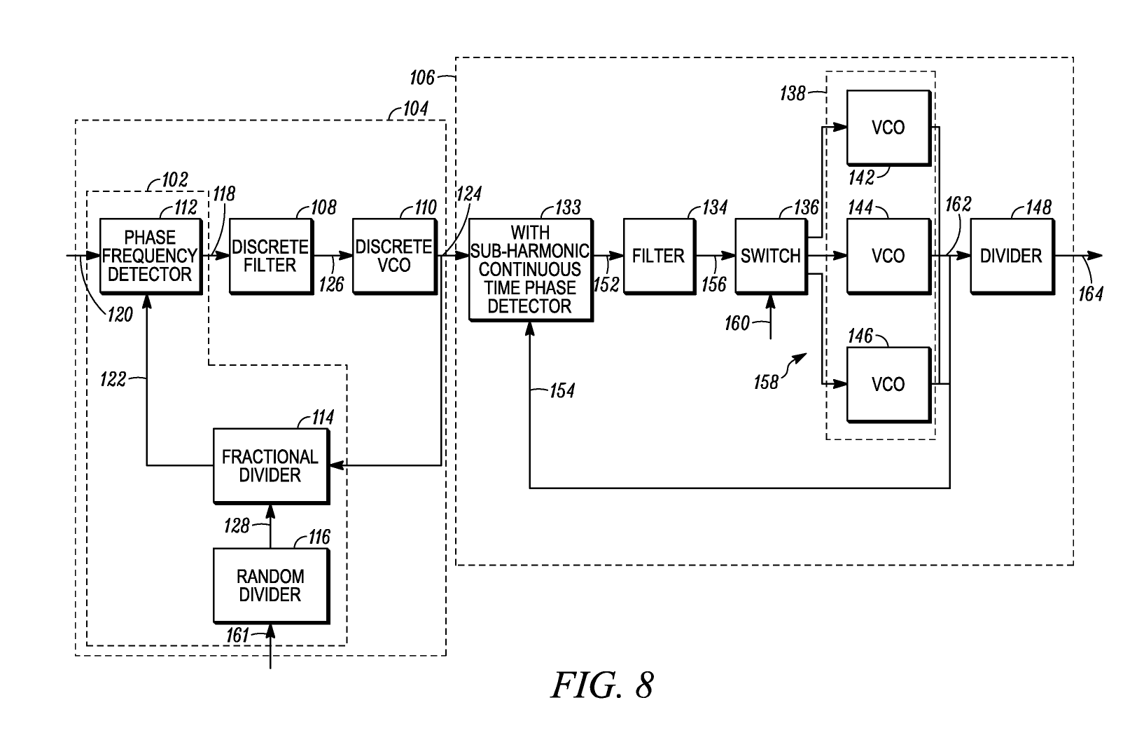

In an alternative exemplary embodiment (FIG. 8), phase detector 132 is a sub-harmonic continuous time sampling phase detector 133 and the integrated voltage controlled oscillator output 162 is directly provided to the sampling phase detector 133 (continuous frequency divider 150 is removed). The sampling phase detector 133, compares samples of the integrated voltage controlled oscillator output 162 phase with time synchronized samples of the discrete voltage controlled oscillator 110 phase, providing a control signal 152. The continuous time samples of the sampling detector 133 are at a periodic rate that is a fractional multiple of the period of the integrated voltage controlled oscillator output signal 162.

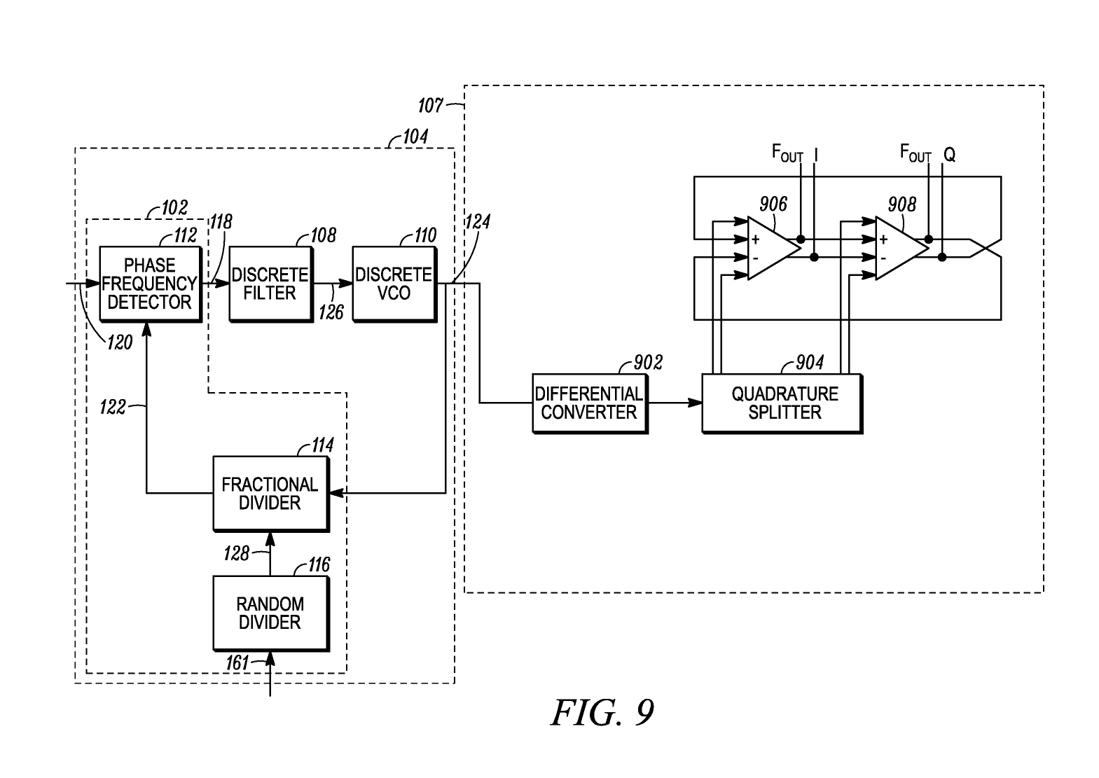

Yet another alternative exemplary embodiment (FIG. 9) utilizes, for the circuitry 105 of FIG. 1, an injection locked ring oscillator 107 with a fractional multiple offset between the period of the ring oscillator outputs 162. The single-ended low noise input signal 124 output by the first PLL 104 is transformed by a differential converter 902 and a quadrature splitter 904 of the injection locked ring oscillator 107 into a set of four signals with frequency of reference signal 124 and quadrature phase offset (90 degree offset 0, 90, 180 and 270 degrees). These four signals are applied to ring oscillator delay networks 906 and 908 of the injection locked ring oscillator 107, thereby locking the output 162 to a fractional multiple of the period of 124. The time delay associated with ring oscillator delay networks 906 and 908 are designed with an approximate fractional delay value of the period of reference signal 124. The result is the improvement of the ring oscillator poor phase noise to a level approaching that of the low phase noise reference signal 124.

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

It will be appreciated that some embodiments may be comprised of one or more generic or specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

Moreover, an embodiment can be implemented as a computer-readable storage medium having computer readable code stored thereon for programming a computer (e.g., comprising a processor) to perform a method as described and claimed herein. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

We claim:

1. A circuit configured to be coupled to a discrete voltage controlled oscillator, the synthesizer architecture comprising:
an integrated portion coupled to the discrete voltage controlled oscillator to form a first phase locked loop wherein the discrete voltage controlled oscillator is configured to provide a low noise reference signal having a first period; and
circuitry coupled to the discrete voltage controlled oscillator and configured to provide, in response to the low noise reference signal, a continuous periodic output with a second period that is a fractional value of the first period.

2. The circuit of claim 1 wherein the circuitry comprises an injection locked ring oscillator.

3. The circuit of claim 1 wherein the circuitry comprises:
a differential converter configured to provide an output in response to the low noise reference signal;
a quadrature offset generator responsive to the output; and
a pair of time delay circuits responsive to an output of the inverter for providing the continuous periodic output.

4. The circuit of claim 1 wherein the circuitry comprises:
an integrated second phase locked loop comprising:
a plurality of integrated voltage controlled oscillators configured to provide an integrated voltage controlled oscillator output in response to a first steering signal;
circuitry coupled to the plurality of integrated voltage controlled oscillators and configured to provide the first steering signal to a selected one of the plurality of integrated voltage controlled oscillators in response to a filtered signal;
a filter coupled to the circuitry to provide the filtered signal thereto;
a phase detector coupled to the integrated voltage controlled oscillators and configured to provide a detector signal to the filter in response to the integrated voltage controlled oscillator output and the low noise reference signal, wherein the detector signal has a continuous periodic output with a period that is a fractional multiple of the integrated voltage controlled oscillators.

5. The circuit of claim 4 wherein the phase detector comprises a sub-harmonic continuous time sampling phase detector.

6. The circuit of claim 4 wherein the phase detector comprises a phase frequency detector, and further comprising a continuous fractional divider coupled between the integrated voltage controlled oscillators and the phase detector, the continuous fractional divider configured to receive the integrated voltage controlled oscillator output and to provide a continuous time fractional divider output to the phase frequency detector.

7. The circuit of claim 6 wherein the continuous time fractional divider output comprises a continuous periodic output having a period that is a fractional multiple of the integrated voltage controlled oscillator.

8. The circuit of claim 4 further comprising an output divider providing a carrier frequency signal within the frequency range of 100 to 941 MHz.

9. The circuit of claim 4 wherein sub harmonic spurs generated by the continuous fractional divider are outside the bandwidth of the filter.

10. The circuit of claim 4 wherein the second phase locked loop is configured to multiply the low noise reference signal by a factor comprising one of the group consisting of 2.5, 3.0, and 3.5.

11. A synthesizer architecture configured to be coupled to a discrete voltage controlled oscillator, the synthesizer architecture comprising:
an integrated portion coupled to the discrete voltage controlled oscillator to form a first phase locked loop wherein the discrete voltage controlled oscillator is configured to provide a low noise reference signal; and
an integrated second phase locked loop comprising:
a plurality of integrated voltage controlled oscillators configured to provide an integrated voltage controlled oscillator output in response to a first steering signal;
circuitry coupled to the plurality of integrated voltage controlled oscillators and configured to provide the first steering signal to a selected one of the plurality of integrated voltage controlled oscillators in response to a filtered signal;
a filter coupled to the circuitry to provide the filtered signal thereto; and
a phase detector coupled to the integrated voltage controlled oscillators and configured to provide a detector signal to the filter in response to the integrated voltage controlled oscillator output and the low noise reference signal, wherein the detector signal has a continuous periodic output with a period that is a fractional multiple of the integrated voltage controlled oscillator signal.

12. The synthesizer architecture of claim 11 wherein the phase detector comprises a sub-harmonic continuous time sampling phase detector.

13. The synthesizer architecture of claim 11 wherein the phase detector comprises a phase frequency detector, and further comprising a continuous fractional divider coupled between the integrated voltage controlled oscillators and the phase detector and configured to receive the integrated voltage controlled oscillator output and to provide a continuous time fractional divider output to the phase frequency detector.

14. The synthesizer architecture of claim 13 wherein the continuous time fractional divider output comprises a continuous periodic output having a period equal to the low noise reference signal that is a fractional multiple of the integrated voltage controlled oscillator.

15. The synthesizer architecture of claim 11 further comprising an output divider providing a carrier frequency signal within the frequency range of 100 to 941 MHz.

16. The synthesizer architecture of claim 11 wherein sub harmonic spurs generated by the continuous fractional divider are outside the bandwidth of the filter.

17. The synthesizer architecture of claim 11 wherein the second phase locked loop multiplies the sideband noise reference signal by a factor comprising one of the group consisting of 2.5, 3.0, and 3.5.

18. A method of providing a carrier frequency signal by a synthesizer architecture comprising a discrete voltage controlled oscillator, comprising:
providing a low noise reference signal by the discrete voltage controlled oscillator; and
providing a continuous periodic output with a period that is a fractional value of a predetermined number in response to the low noise quality reference signal.

19. The method of claim 18 wherein the providing a continuous periodic output comprises:
continuously time sub-harmonic fractional detecting the noise quality reference signal in response to the carrier frequency signal for providing a control signal; and
providing the carrier frequency signal by a selected one of a plurality of voltage controlled oscillators, wherein the selected voltage controlled oscillator is responsive to the control signal.

20. The method of claim 18 wherein the providing a continuous periodic output comprises:
providing the carrier frequency signal by a selected one of a plurality of integrated voltage controlled oscillators;
continuously fractional dividing the carrier frequency signal to provide a continuous time fractional divider output;
detecting the low noise quality reference signal and the continuous time fractional divider output; and
providing a wide bandwidth phased detector output to the selected integrated voltage controlled oscillators in response to the detecting step.

21. The method of claim 18 wherein the providing a continuous periodic output comprises:
converting the continuous periodic output into four signals having a quadrature phase offset; and
delaying the four signals, thereby locking the continuous periodic outputs to a fractional multiple of the period of continuous periodic outputs.
